(19) United States
(12) Patent Application Publication
(10) Pub. No.: US 2018/0330874 A1
(43) Pub. Date: Nov. 15, 2018

(54) MANUFACTURING METHOD FOR A SENSING ELEMENT AND SENSOR DEVICE

(71) Applicants: JAQUET TECHNOLOGY GROUP AG, Basel (CH); FRAUNHOFER-GESELLSCHAFT ZUR FÖRDERUNG DER ANGEWANDTEN FORSCHUNG E.V, Munchen (DE)

(72) Inventors: Andreas Tuor, Lausanne (CH); Oliver Hirsch, Schallbach (DE); Martin Ihle, Dresden (DE); Steffen Ziesche, Dresden (DE)

(73) Assignees: JAQUET TECHNOLOGY GROUP AG, Basel (CH); FRAUNHOFER-GESELLSCHAFT ZUR FÖRDERUNG DER ANGEWAND TEN FORSCHUNG E.V, Munchen (DE)

(21) Appl. No.: 16/040,699

(22) Filed: Jul. 20, 2018

Related U.S. Application Data
(63) Continuation of application No. PCT/CH2017/000005, filed on Jan. 11, 2017.

(30) Foreign Application Priority Data
Jan. 20, 2016 (CH) 0079/16

(51) Int. Cl. H01F 41/04; H01F 27/28; H01F 27/29; F02C 6/12; F04D 29/02; F04D 29/28; G01P 3/49; G01P 1/02

(52) U.S. Cl. CPC H01F 41/043; H01F 27/2804; H01F 27/29; F02C 6/12; F04D 29/023; F04D 29/284; F05D 2270/80; G01P 1/026; H01F 2027/2809; F05D 2220/40; F05D 2240/14; F05D 2240/30; F05D 2300/50; G01P 3/49

(57) ABSTRACT

A method for manufacturing a sensor module having a passive electrical component comprises punching a plurality of holes in a first green sheet of a plurality of green sheets, and forming a plurality of channels and a plurality of passageways in a second green sheet of the plurality of green sheets by using a laser on the second green sheet. A metallization paste is printed in the plurality of holes, the plurality of channels, and the plurality of passageways, and the first green sheet and the second green sheet are dried with the metallization paste. The method further comprises aligning, stacking, laminating, and sintering the plurality of green sheets together to create a sintered tile, and separating a plurality of coils of the sintered tile in order to obtain the sensor module.

### CROSS-REFERENCE TO RELATED APPLICATIONS

This application is a continuation of PCT International Application No. PCT/CH2017/000005, filed on Jan. 11, 2017, which claims priority under 35 U.S.C. § 119 to Swiss Patent Application No. 0079/16, filed on Jan. 20, 2016.

### FIELD OF THE INVENTION

The present invention relates to a manufacturing method for a sensing element and, more particularly, to manufacturing method for a sensing element using low temperature co-fired ceramics.

### BACKGROUND

Low temperature co-fired ceramics (LTCC) are known in electronics for manufacturing electronic circuits with multiple layers on sintered ceramic substrates. Conductor paths, capacitors, coils, etc. can be manufactured by LTCC. An advantage of LTCC circuits is the possibility of integrating these passive electric components into a ceramic casing, which is advantageous in difficult operating conditions such as dirty and hot environments, as the ceramic casing has good thermo-mechanical and protective properties. Because of the low firing temperature of 850° C. to 900° C. it is possible to use metals with low power dissipation for circuit paths, typically gold or silver, the melting points of which are between 960° C. and 1100° C. The low power dissipation reached by using said metals confers outstanding high frequency properties on modules manufactured by LTCC technology.

An LTCC module is a single or multiple layer substrate consisting of one or more layers of a dielectric tape made of a glass ceramics material and called “green sheet” or “green tape”. Passive components like coils may be embedded in this substrate or they may be applied on the uppermost layer.

In an exemplary turbocharger application, coils are used to sense the rotational speed of compressor blades. A turbocharger uses waste energy from the exhaust gas of an automotive engine to drive the intake and compression of fresh air, which is then forced into the automotive engine. This results in the engine burning more fuel and thus producing more power, while less energy is consumed, thereby improving the overall efficiency of the combustion process. A turbocharger typically comprises a turbine wheel and a compressor wheel, which are connected by a common shaft supported on a bearing system. The turbine wheel is driven by the exhaust gas which in turn drives the compressor wheel, the compressor wheel drawing in and compressing ambient air which is then fed into the engine's cylinders. By turbocharging, the performance level of smaller engines can be increased up to the performance level of bigger engines without turbocharging, with the added benefits of lower fuel consumption and emissions. Consequently, turbochargers are increasingly employed with diesel and gasoline engines in passenger, commercial, off-road and sport vehicles.

Determining rotational speed of the compressor wheel of a turbocharger is important for optimizing its efficiency, and for ensuring that a turbocharger and engine stay within their respective safe operational ranges. Current turbochargers need to operate reliably and continuously with increasingly higher exhaust gas temperatures and compressor inlet temperatures. Modern gasoline and diesel turbochargers have to operate in a much higher under-hood temperature environment, with temperatures at the compressor wheel being around 200° C. or above. Modern turbocharger compressor wheels are typically constructed from strong, lightweight conductive materials such as aluminum, titanium, or magnesium which can tolerate high stresses. Rotational speed of such compressor wheels can be measured, preferably by an active eddy current principle, wherein a magnetic field is generated by an oscillating system and a sensing coil is used to detect compressor blades when they pass through the magnetic field in front of the sensor tip.

Modern applications for measuring turbocharger speed are technically challenging because impeller/compressor wheels (the target wheels) are typically very thin (a few tenths of a millimeter), in particular for passenger cars, and therefore generate a low signal for the sensor coil to detect. Also the sensing distance/air gap, i.e., the distance between the sensing element, which is typically a standard flat coil such as a pancake coil, and the target blades varies as the coil is flat, while the interior wall of the turbocharger housing is round/saddle-shaped and the envelope of the impeller/compressor wheel is curved. Consequently, these coils have a relatively large shape in order to be able to gain enough signal that can be processed for computing said rotational speed. However, these applications require small coils in order to be able to fit them into a relatively small sensor tip such that negative side effects, such as hotspots and aerodynamic disturbances, are avoided or at least minimized. Consequently, the coil diameter defines the size of the sensor tip. The size and position of the coil relative to the blades are decisive parameters for attaining accurate measurement results.

Factors influencing the quality of rotational speed measurement results for turbochargers are, amongst others:

Thickness of the blades—The thickness of the blades has an influence on the signal shape and amplitude. The thinner the blades are, the more difficult it is to sense them correctly.

Material of blades—Materials with low electrical conductivity like titanium influence the signal shape and amplitude, resulting in low sensitivity.

Air gap width between the sensor tip and the blades—In order to get more accurate results, the air gap (distance) between the coil in the sensor tip and the passing blades has to be as small as possible. Therefore, the dimensions and shape of the coil play a very important role.

Due to these three main factors, the optimization of coil geometry and dimensions has to be taken into account in order to accurately measure speed.

Generally, winding processes are known and used for manufacturing coils. However, such processes only allow manufacturing of coils having simple geometries, such as pancake coils. Due to their instability, such coils may be deformed during an overmolding process, resulting in an inconsistent and aberrant signal processing.

In order to reach an acceptable small size of the coil for applications requiring small coils, the wound coil solution has proven functional but the result is only a compromise between signal quality, signal shape, air gap and size of the sensing element. As a consequence, the signal shape and quality are not satisfactory. For said example of turbocharger applications, the above solution is practicable, however at the expense of signal quality and shape. It is alternatively possible to increase coil size for signal optimization, however at the expense of the other parametric requirements of the speed sensor, thus resulting in a worse form factor of the sensor tip and an unfavorable air gap.

The alternative to wound coil processes is to manufacture coils in a standard, classical ceramic multi-layer technology. However, such coils show a rather poor sensorial performance because the usual layer deposition step in combination with the sintering step limits the dimensions of the deposited coil windings. Maximum metallization thicknesses reached with this process are of about 10 to 20 μm. Thicker layers lead to squeezing (potentially resulting in short circuits between the winding), and can also result in warping or cracking of the ceramic during the sintering process. There are also confinements regarding the line/space dimensions. Typical screen-printing results in 200/200 μm dimensions. Small cross sections of the printed conductor lines and large distances (laterally and vertically) between the different metallization layers and wires results in low inductance and high resistance of the coils. Hence, the quality factor of such coils is rather low, resulting in poor sensor performance.

Further current manufacturing approaches include embossing of channels into the ceramic green tape combined with a further filling process by screen printing. The disadvantage of this approach is the limited embossing channel depth (typically below 30 μm) and restricted space (typically greater than 70 μm) of such structures, which results in high resistances of the metallization structures.

International patent application WO 2015/027348 discloses a sensor device comprising a sensor housing with a sensor segment, a mounting segment, and a connector segment. The sensor segment and the connector segment are arranged on opposite sides of the mounting segment. A sensing element is arranged at the sensor tip of the sensor segment with the expression “sensor tip” referring to that end of the sensor segment which is furthest away from the mounting segment. Furthermore, sensor electronics are arranged inside the sensing segment, the sensor electronics comprising a silicon-on-insulator circuit. The integrated silicon-on-insulator circuit is embedded between flexible or semi-flexible polymer substrates. The sensor electronics provide input signals to the sensing element and/or evaluate and/or amplify output signals/measurement signals provided by the sensing element. WO 2015/027348 also outlines the measurement basics of said rotational speeds known by those of ordinary skill in the art.

### SUMMARY

A method for manufacturing a sensor module having a passive electrical component comprises punching a plurality of holes in a first green sheet of a plurality of green sheets, and forming a plurality of channels and a plurality of passageways in a second green sheet of the plurality of green sheets by using a laser on the second green sheet. A metallization paste is printed in the plurality of holes, the plurality of channels, and the plurality of passageways, and the first green sheet and the second green sheet are dried with the metallization paste. The method further comprises aligning, stacking, laminating, and sintering the plurality of green sheets together to create a sintered tile, and separating a plurality of coils of the sintered tile in order to obtain the sensor module.

### BRIEF DESCRIPTION OF THE DRAWINGS

The invention will now be described by way of example with reference to the accompanying Figures, of which:

FIG. 1A is a schematic view of steps of a method according to the invention of processing a first green sheet;

FIG. 1B is a schematic view of steps of the method of processing a second green sheet;

FIG. 1C is a schematic view of a stacked plurality of green sheets according to the method;

FIG. 2 is a top view of a stencil used in the method of FIG. 1B;

FIG. 3 is a perspective view of a coil according to an embodiment of the invention;

FIG. 4 is a top view of the coil of FIG. 3;

FIG. 5 is a side view of the coil of FIG. 3;

FIG. 6 is an enlarged portion of the side view of the coil of FIG. 5;

FIG. 7 is a top view of a structured tile before separation of a plurality of coils;

FIG. 8 is a perspective view of a sensor module according to the invention;

FIG. 9 is a top view of the sensor module of FIG. 8;

FIG. 10 is a perspective view of a sensor device according to an embodiment of the invention;

FIG. 11 is a perspective view of a supporting element of the sensor device of FIG. 10; and

FIG. 12 is a sectional side view of a turbocharger incorporating the sensor device of FIG. 10.

### DETAILED DESCRIPTION OF THE EMBODIMENT(S)

Exemplary embodiments of the present invention will be described hereinafter in detail with reference to the attached drawings, wherein like reference numerals refer to like elements. The present invention may, however, be embodied in many different forms and should not be construed as being limited to the embodiments set forth herein. Rather, these embodiments are provided so that the present disclosure will be thorough and complete and will fully convey the concept of the disclosure to those skilled in the art.

Throughout the specification, the terms “above”, “below” and the like are meant with respect to the environment of the respective component. Therefore, for example, a first layer arranged above a second layer is closer to the environment than the second layer.

The term “complex geometry” or “complex geometries” is interpreted for coils in the specification as a two-dimensional coil structure which cannot be wound or a three-dimensional coil structure. The specification only describes an exemplary geometry for the purpose of explaining the features of the invention; other geometries are readily possible.

The term air gap is understood as a distance from a sensor tip to an object to be measured. In this context the distance is understood as being the distance from the sensor tip with the sensor module to the closest point of the object to be measured.

In the context of the present invention, a “sensing element” is understood as a general term for a product manufactured by the method according to the invention described below. A “coil” manufactured by the method according to the invention is the electrical component inside the sensing element. It is noted that the “sensing element” may consist of the coil or it may comprise the coil as said passive electrical component together with additional layers. In other words the method steps can be applied to only manufacturing a coil, e.g. a two-layered coil, but they are equally valid in case additional layers are required which are not part of the passive electrical component (coil). A “sensor module” comprising a “coil” may be manufactured by the method according to the invention in one process of manufacturing the coil and adding additional layers above the coil. The term “sensor module” is to be understood as the sensing element comprising additional layers to the electrical component. A “sensor device” is a device containing the sensing element and also other parts which are not manufactured by the method according to the invention. Therefore, the sensor device may comprise only the coil as sensing element or a sensor module.

The term “under pressure” is understood as subjecting the respective entity to a pressure above atmospheric pressure.

Throughout the specification, “metallization” refers to metallized channels and/or metallized passageways.

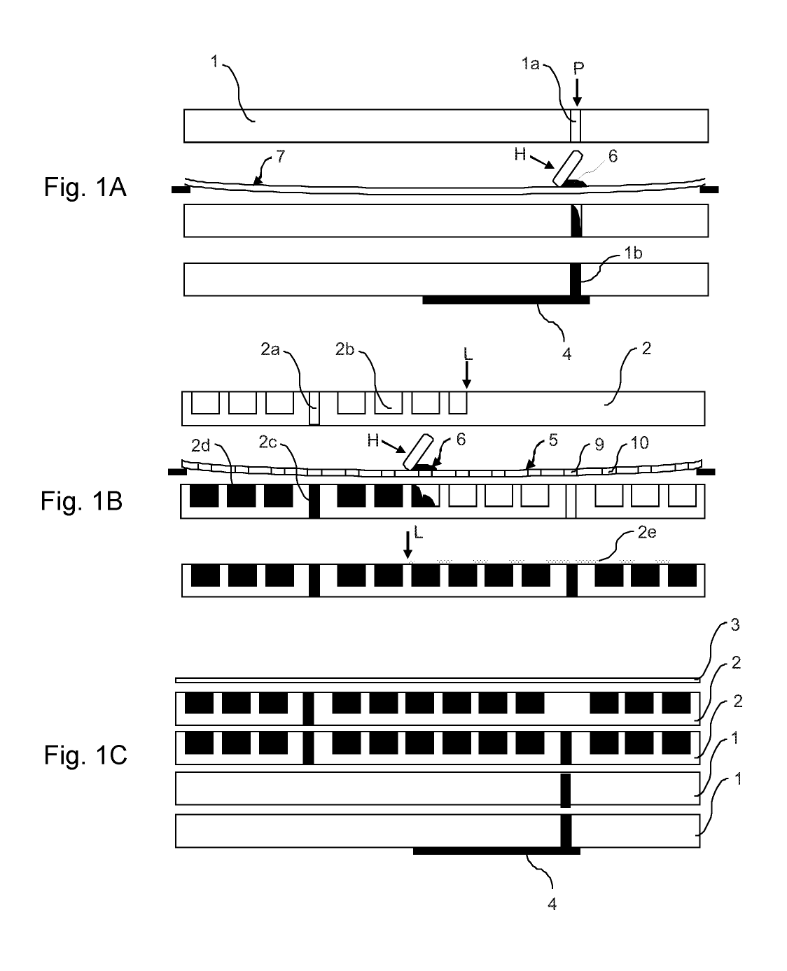

A method of manufacturing a sensing element according to an embodiment of the invention is shown in FIGS. 1A-1C. The method shown in FIGS. 1A-1C starts with green sheets 1, 2, 3 having no channels.

In a first optional step, all used green sheets 1, 2, and 3 are tempered by removing at least parts of solvent from them. Those green sheets 1, 2, 3 form an unsintered ceramic entity, i.e. a ceramic plate which has not been otherwise processed by the method. Generally, green sheets 1, 2, 3 are available in different standard dimensions. Tempering the green sheets 1, 2, 3 has a positive effect later during the process, at a step of stencil printing and drying, and during a second optional step of laser cleaning. As the step of drying exposes the raw ceramic entity to heat, the layers shrink due to evaporation of solvents. It has been noticed that this shrinkage of green sheets 1, 2, 3 does not take place uniformly throughout its extension but the rate is different at the edges as compared to the middle of the green sheets 1, 2, 3. This causes undesired deformations of the green sheet surface, which may have an impact on the whole module to be manufactured. By tempering, parts of solvents are extracted from the green sheet 1, 2, 3, thus yielding later a more uniform, reduced shrinkage of the green sheets 1, 2, 3.

FIG. 1A shows a processing on a first green sheet 1 of the green sheets 1, 2, 3. Holes 1a for contacts are punched P in the green sheet 1 and the holes 1a are filled and metallized to form contacts 1b extending through the green sheet 1. In order to ensure a uniform filling of the holes 1a, a printing head H moves a metallization paste 6 forward and backward over a stencil 7. The contacts 1b are then formed by drying the first green sheet 1 and connect a coil to the pad 4 of the sensor element.

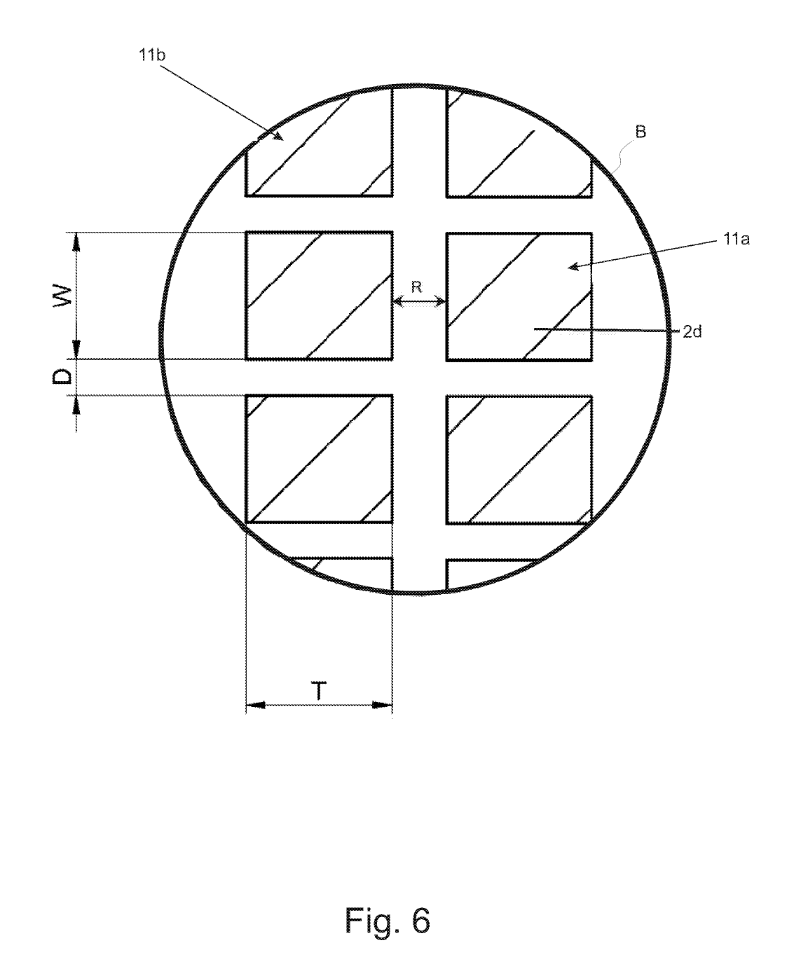

As shown in FIG. 1B, channels 2b and passageways 2a are formed by lasering L in a second green sheet 2. The channels 2b and passageways 2a are filled and metallized and dried to form filled passageways 2c, which connect the coil and the pad 4, and filled channels 2d. In an embodiment, the lasering L uses a UV-laser with adequate energy output. In an embodiment, a high precision laser tool is used that has low geometrical distortion, as the structure to be processed by the laser is very small, as is described below with reference to FIG. 6.

In an embodiment, the channels 2b are formed gradually in multiple lasering sub-steps until uniform channel depth is obtained. Using at least three sub-steps, wherein in each sub-step at least a portion of green sheet 2 material is removed in the region for metallization by the laser, a uniform channel consistency is achieved without being excessively time consuming. This sub-step-process also forms channels 2b with small dimensions while avoiding a potential “through-lasering” of the entire green sheet 2.

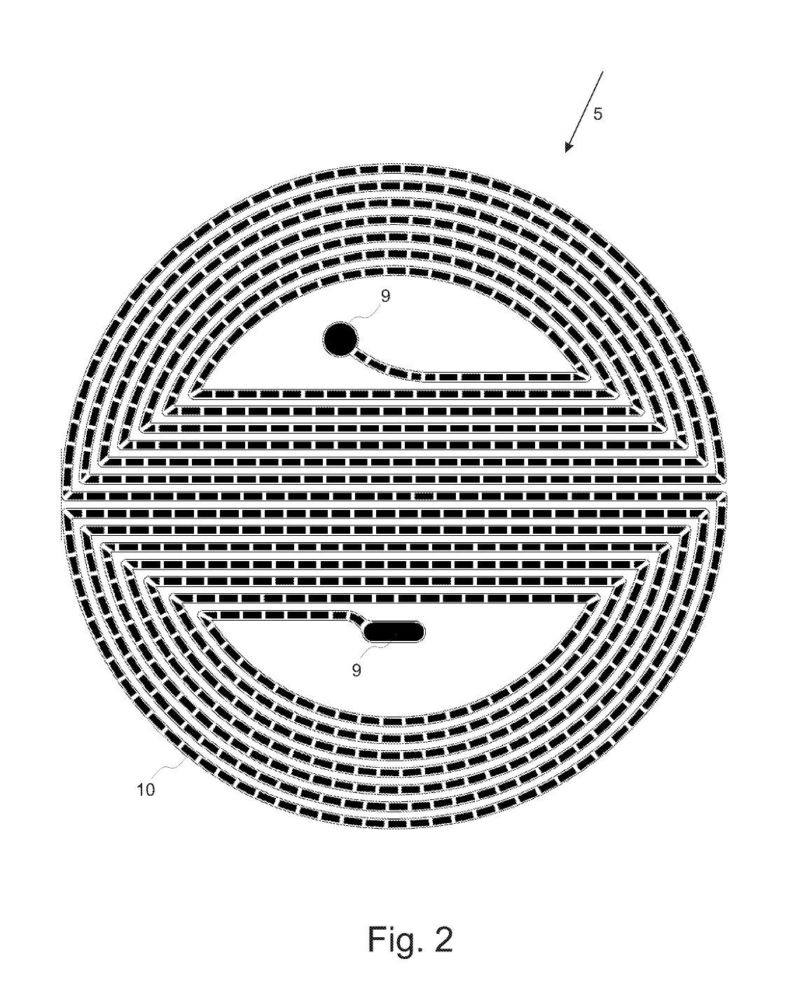

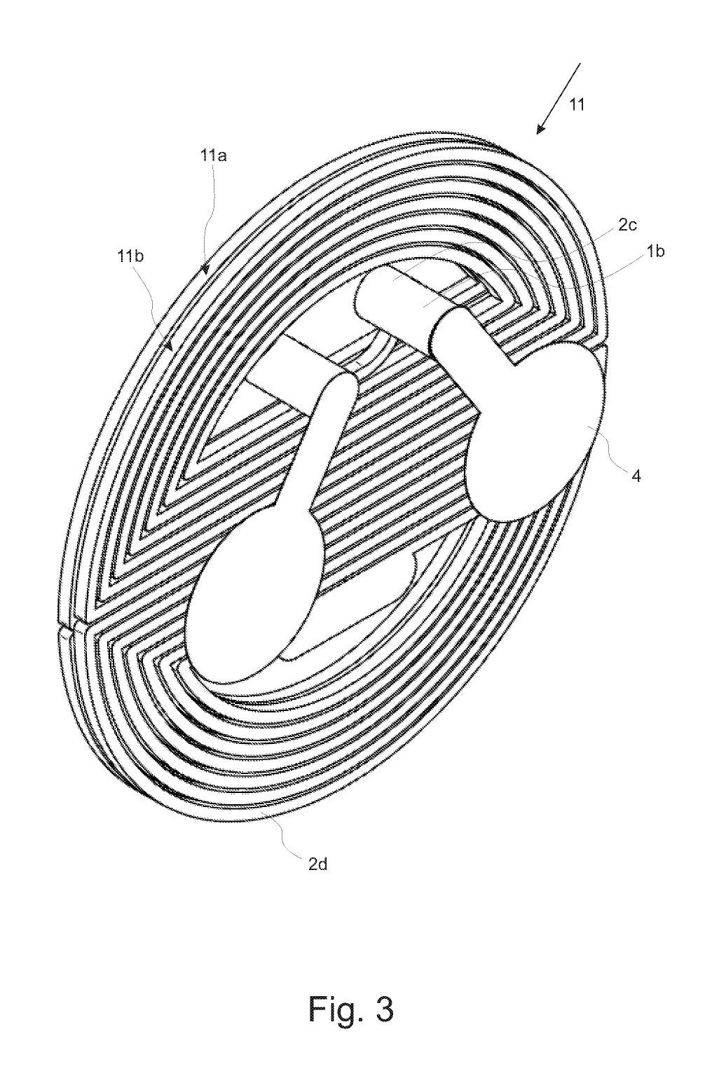

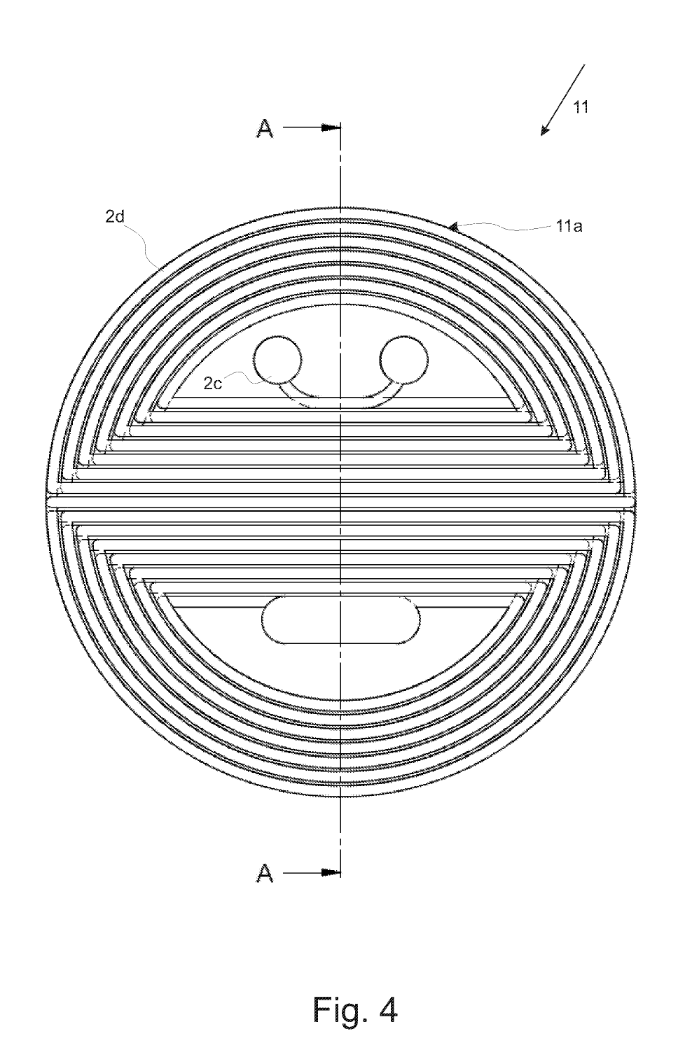

As shown in FIG. 1B, empty holes 2a and empty channels 2b are filled by stencil printing through a stencil 5 using printing head H with a metallization paste 6. The stencil 5 is described in more detail below with reference to FIG. 2.

In an optional step shown in FIG. 1B, residual metallization paste 2e between neighboring channels 2b is removed by lasering L. During the optional laser-cleaning step, the residual metallization paste 2e on the surfaces between the filled channels 2d is removed by the laser L, wherein the above mentioned UV-laser, such as a diode-pumped solid state laser, is used. This step increases in importance the higher the level of miniaturization. For example, in case of inter-channel 2b spaces of 30 μm or below, metallization paste residuals 2e can remain on the surface of the green sheet 2 between two adjacent channels 2d, therefore leading to short-circuits. These metallization paste residuals 2e are removed by the cleaning process, wherein the cleaning time is significantly below one second per coil.

In the embodiment shown in FIG. 1C, the plurality of green sheets 1, 2, 3 are stacked one above the other and aligned after the laser cleaning in order to form the raw ceramic entity. A thin third green sheet 3 without metallization is added as an outermost green sheet before sintering the raw ceramic entity in order to protect the electrical passive component or the electrical circuit “buried” in the inner layers 1, 2. The method shown in FIGS. 1A-1C can be used for manufacturing single layer or multiple layer entities.

FIG. 1C shows an exemplary stack of layers 1, 2, 3, of which outermost layer 3 is a protective layer. The following two layers 2 represent a circuit or a passive electrical component with channels 2d and holes 2c already filled with metallization paste 6. The subsequent two layers 1 are exemplary optional layers having only filled holes 1b for establishing electrical contact to the external sensor electronics. At least two pads 4 are printed on one side of the coil for connection to the sensor electronics. FIG. 1C shows a stage in which the already prepared layers are ready to be stacked.

The raw ceramic entities are then aligned, stacked, laminated and sintered for creating the final tile before separating the single coils. In the standard LTCC-process integrating high amounts of metallization paste 6 into a ceramic layer or multilayer commonly results in warping or in defects during a standard firing process or sintering process. These undesired effects occur due to differences in shrinkage rate and absolute shrinkage of the metallization paste 6 and the dielectric base material of the green sheets 1, 2, 3. Other reasons for warping are the diffusion of the metal of the metallization paste 6 into the ceramic base material of the green sheet 1, 2, 3, leading to non-uniform shrinkage of the ceramic, and therefore to the creation of defects. The method of the present invention uses a constrained sintering process which differs from the standard sintering process and is carried out under pressure. In an embodiment, a pressure of around 0.1 MPa to 0.8 MPa is sufficient for good results. In other embodiments, other pressures may be applied.

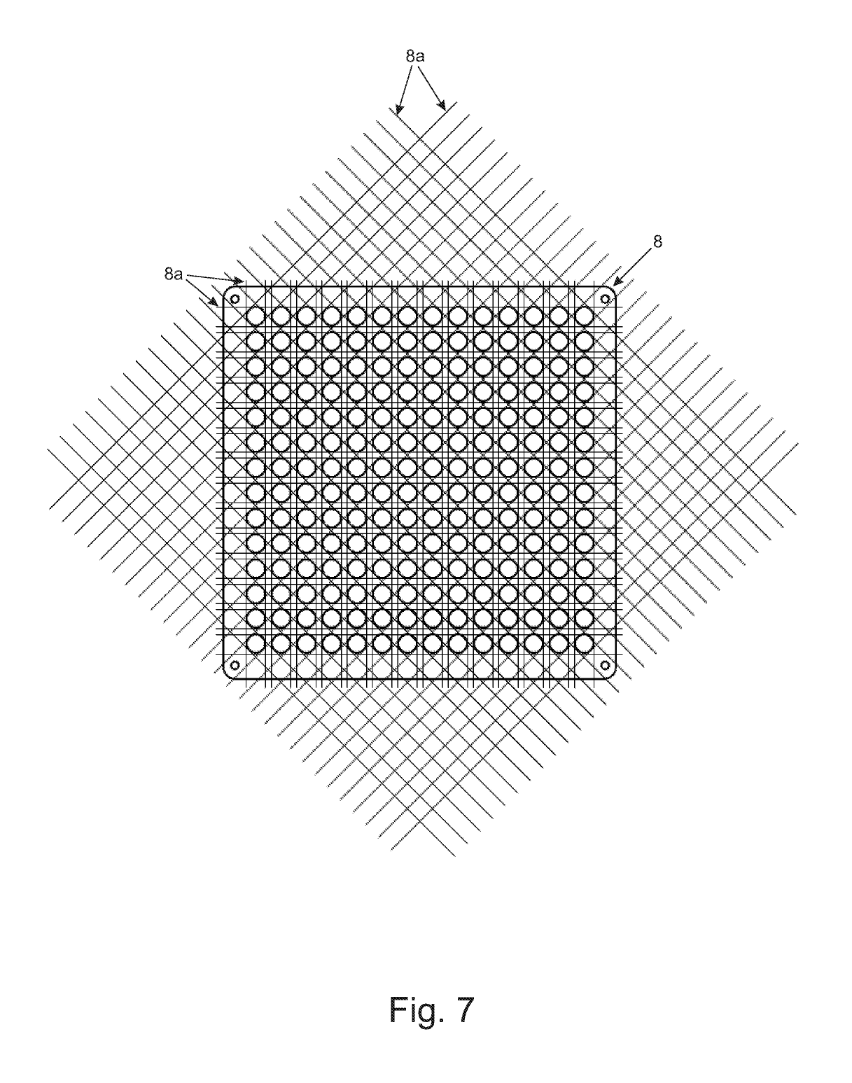

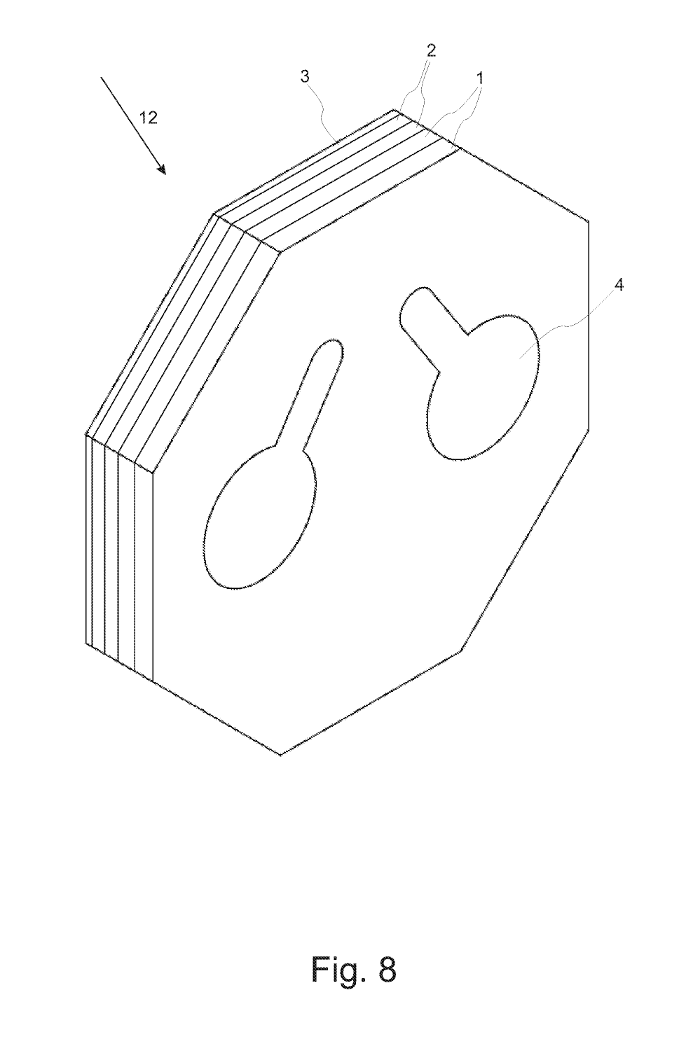

The coils are then separated by sawing, laser cutting, or scribing and breaking in order to create the final sensing element. In order to optimize the coil density on the tile and simplify the separation procedure by minimizing the number of sawing or lasering steps, the contour of the sensing entity must be chosen carefully, e.g. an octagon for sawing as shown in FIG. 7. In order to simplify this process, alignment marks are printed around each coil.

The stencil 5 for filling the empty holes 2a and empty channels 2b, as shown in FIG. 1B, is shown in greater detail in FIG. 2. The stencil 5, as shown in FIG. 2, includes openings 10 for channels 2b and openings 9 for holes 2a such that metallization paste 6 can be introduced into the empty channels 2b and the empty holes 2a via the printing head H. The openings 10 of the stencil 5 are equally spaced and are arranged section-wise along the stencil 5 in order to improve stability of the stencil 5. Metallization paste 6 pushed into two adjacent openings 10 will also fill channel sections which are covered by stencil material between two adjacent stencil openings 10. The stencil 5 comprises a polymer structure layer for regulating the amount of metallization paste 6 to be filled in the channels 2b and holes 2a. The metallization paste 6 is a conductive paste with a defined solid phase, e.g. silver with solvent. The holes 2a and channels 2b are filled simultaneously. In order to ensure a uniform filling of the channels 2b with metallization paste 6, the printing head H has to be moved forward and backward in several directions in the horizontal plane.

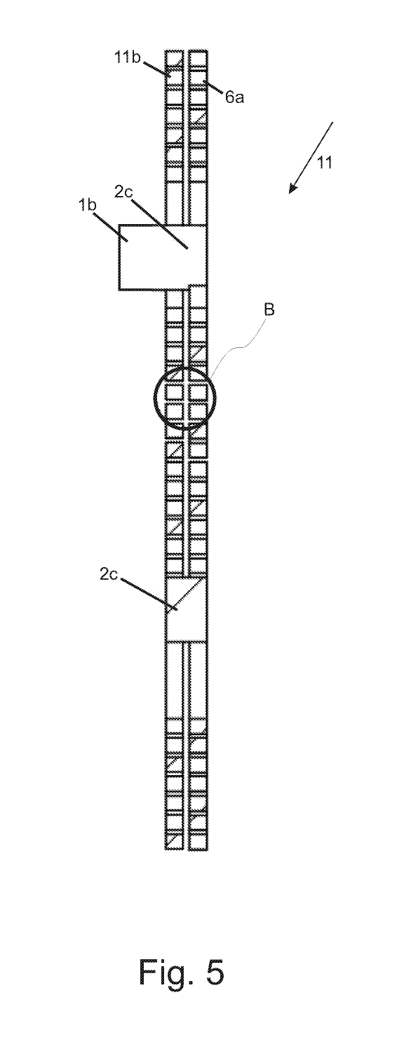

A coil 11 shown in FIGS. 3-6 is a sensor module 12 manufactured by the method according to the invention described above. The coil 11 is arranged on two green sheet layers 2.

If additional layers to the coil layer are present, the coil 11 forms the passive electrical component of the sensor module 12. In this example, the coil 11 consists of two coil layers 11a and 11b corresponding to two green sheets 2 as shown in FIGS. 1A-1C. To simplify the illustration, only the metallization paths forming the coil winding are shown in FIG. 3. As shown in FIG. 3, contacts 4 for connecting the coil 11 to the sensor electronics are provided, wherein one contact 4 is connected to one end of the winding of the coil 11 and the other contact 4 is connected to the other end of the winding of the coil 11.

In various embodiments, the coil 11 is a double-D flat coil or a double-D saddle-shaped coil. In other embodiments, other coil geometries may readily be manufactured. For example, a coil 11 may be implemented on one single layer or multiple layers, either as a two-dimensional coil or a three-dimensional coil, depending on the required geometry.

As shown in FIG. 6, the metallizations 2d of the coil 11 have an aspect ratio larger than 1. The aspect ratio is defined by depth T of the channel 2d divided by its width W, yielding for the present case T/W>1. The depth T of each channel 2d ranges between 80 und 120 μm in a non-sintered green sheet 2 with a thickness of 165 μm. The channel depth T depends on the advised metallization thickness and is controlled precisely by lasering steps during the forming process in order to yield uniformly deep channels over the entire structure. This channel depth T predominantly determines the internal resistance of the metallization structure. The residual green sheet thickness R remaining after channel formation, as during multiple sub-step channel formation described above, determines the distance between metallization of the different coil layers and influences the inductivity and capacity of the coil 11. The width W of each filled channel 11a and 11b for the metallizations is about 70 μm. In embodiments, the distance D between two neighboring filled channels of 11a and 11b ranges between 20 und 30 μm.

The dimensions reveal the necessity of using a high precision laser for forming the channels 2b in the green sheets 2. The usefulness of the optional cleaning step in the manufacturing method is also apparent, as the channel interspaces D are only 25 μm wide, for example. Without the cleaning step it would be likely that small metallization paste 6 portions could easily bridge this width, thereby creating shorts.

A structured tile 8 ready for sawing, laser cutting, or scribing-and-breaking along the separation lines 8a is shown in FIG. 7. Four different directions are followed, horizontal, vertical, +45° and −45° in order to obtain an octagonal sensing module 12 containing the coil 11 described above.

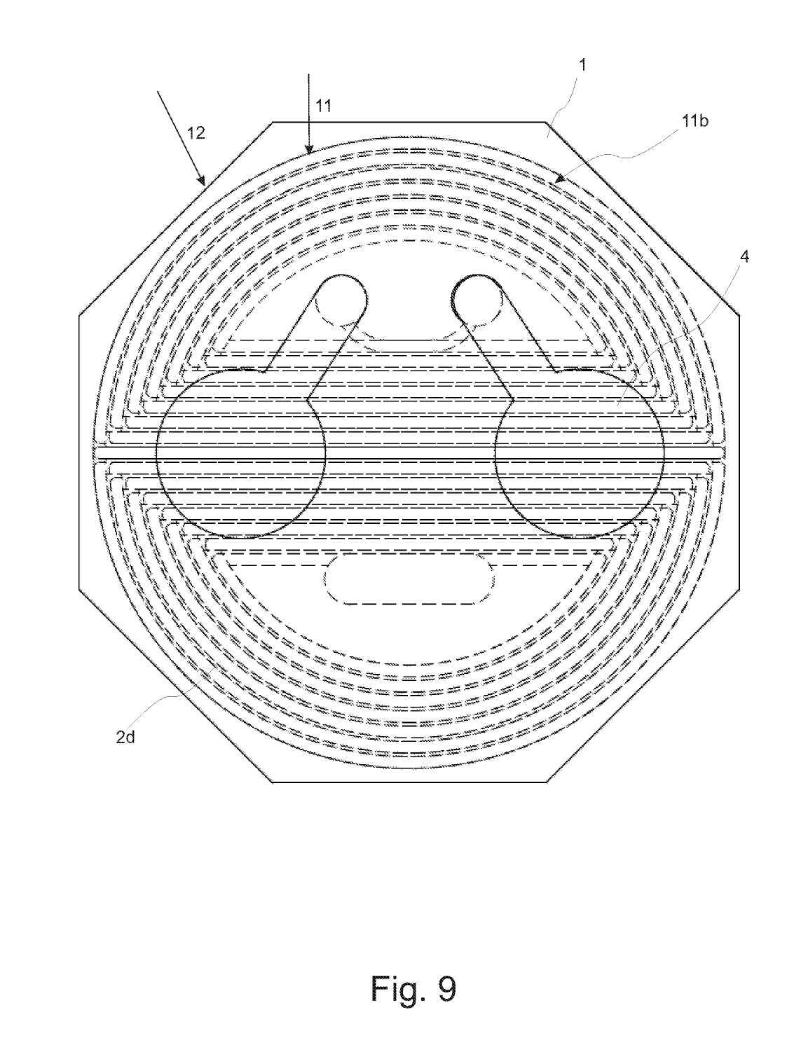

A sensor module 12 according to the invention is shown in FIGS. 8 and 9. The sensor module 12 comprises the coil 11, indicated by the layers 11b, and further green sheets in addition to the two green sheets 2. Outermost green sheets 3 and two green sheets 1 of the sensor module 12 sandwich the two green sheets 2 having the coil 11. The green sheets are intended for protection of the coil 11. Connector holes 1b are provided in green sheets 1. Electrically conductive connector surfaces 4 for the coil 11, used for connecting the sensor module 12 to the sensor electronics, are printed on the outmost green sheet layer 1. In other embodiments, further layers may be arranged between the coil layers 2 and the outermost layer 1.

The connector surfaces 4 are arranged on one side of the sensor module 12 in the outermost green sheet 1, as shown in FIG. 8. The outermost surface 3 is a plain green sheet with neither channels nor holes. It is, however, also possible to arrange one connector surface 4 on one side of the coil 11 and the other connector surface 4 on the other side of the coil 11.

In embodiments, and particularly in embodiments related to the application of the sensor module 12 in turbo-chargers, the sensor module 12 has a minimum diameter of 3 mm, or a diameter of 3.7 mm. A maximum diameter is not given as there is no particular restriction on this parameter; the only limitation is given by the application where the sensor module 12 is used and by limitations of the manufacturing process.

The sensor module 12 is manufactured by the method described above. At the first optional step, all green sheets 1, 2 and 3 are tempered. The green sheets 1 only containing holes are then punched in order to create the contacts 1b for electrically connecting the coil 11 to an external circuit. The subsequent steps described above are then applied to the green sheets 2 intended for the coil 11. Before the sintering step, the already mentioned steps of aligning, stacking and lamination of all green sheets 1, 2, 3 is performed. The result is a very compact and robust sensor module 12, which allows usage of the sensor module 12 in harsh environments.

The method according to the invention is carried out in accordance with the type of layer used. Suitable controlling procedures and software are used to adapt the method to the particular requirements, for example, to skip one or more steps for layers which don't require the one or more steps. Furthermore, the controlling software may trigger repeating of individual steps of the method before subsequent steps are executed, e.g. the step of forming channels, which is carried out gradually in at least three sub-steps. In embodiments the controlling software may also trigger “parking” green sheets until they are used. For example, if the first optional step is carried out for a plurality of layers which include green sheets requiring through-holes and channels and also green sheets not requiring these steps, the latter green sheets may be “parked” until the layers requiring channels and through-holes have been processed. Only after this processing the parked green sheets are introduced into the process again for the stacking step. In this embodiment, all layers experience the same shrinkage in a common process step. In another embodiment, it is possible to process the parked sheets individually.

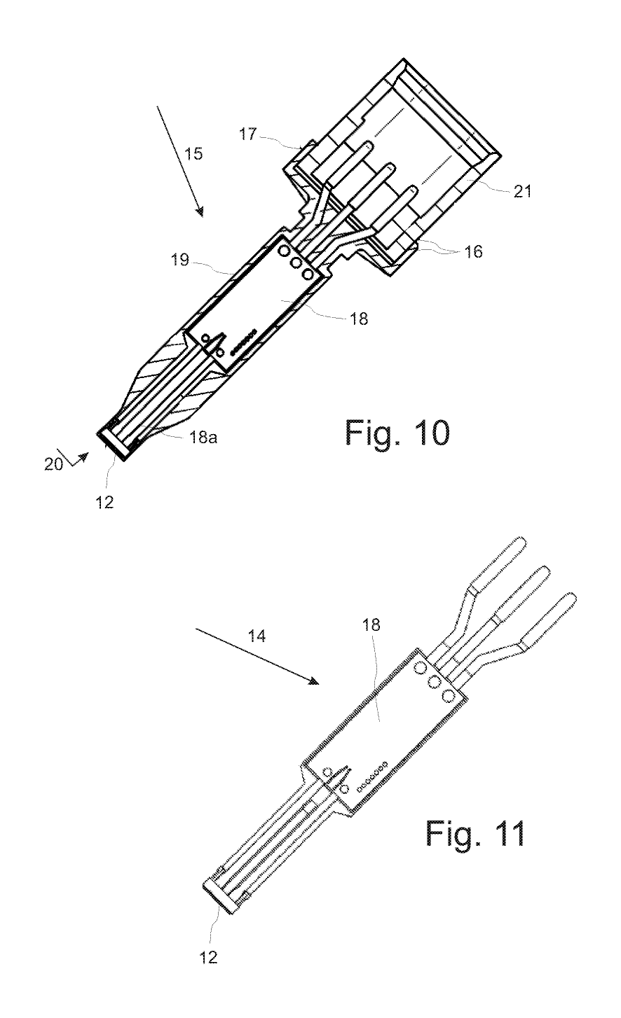

A sensor device 15 according to the invention is shown in FIG. 10. The sensor device 15 is used for determining a speed of an electrically conductive object passing in front of the sensor device 15. In an embodiment, the object is a blade 23 of a turbocharger impeller 25, as shown in FIG. 11. The sensor device 15 comprises a sensor housing 16 and a sensor module 12 arranged at an extremity 20 or sensor tip of the sensor housing 16 and facing in a direction of expected passing of the blade 23. The sensor module 12 is connected to sensor electronics 18 for signal processing and data transmission, arranged inside the sensor housing 16.

The sensor housing 16, as shown in FIG. 10, comprises a sensor segment 19, a mounting segment 17, and a connector segment 21 with the mounting segment 17 connecting the sensor segment 19 and the connector segment 21 such they are on opposite sides of the mounting segment 17. The mounting segment 17 is formed as a flange in an embodiment. The sensor module 12 is arranged inside the sensor tip 20 of the sensor segment 19. The sensor module 12 and the sensor electronics 18 are connected to one another by contacts 18a which are connected to contact pads of the sensor electronics 18 and pads 4 of the sensor module 12. The sensor electronics 18 and the contacts 18a are mounted on a supporting element 14, shown in FIG. 11, which defines the correct place of the sensor electronics 18, the contacts 18a, and the sensor module 12.

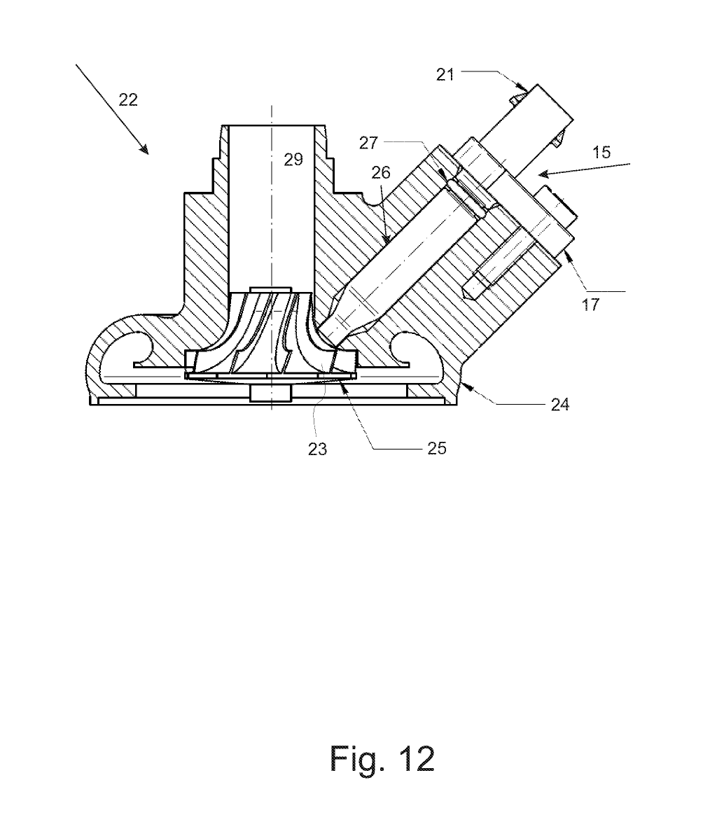

A turbocharger 22 according to the invention with the sensor device 15 of FIG. 10 is shown in FIG. 12. The turbocharger 22 comprises a casing 24, a compressor wheel 25 with compressor wheel blades 23, and a sensor device 15. The compressor wheel blades 23 are made of an electrically conductive material such as titanium, nickel, or aluminum. In various embodiments, the thickness of the compressor wheel blades 23 is equal to or larger than 0.2 mm. The sensor tip 20 of the sensor device 15 faces the compressor wheel blades 23.

The turbocharger 22, as shown in FIG. 12, further comprises a compressor inlet 29 inside the casing 24. The compressor wheel 25 is connected to a turbine wheel by a shaft. The casing 24 has a recess in form of a passageway 26, in particular a cylindrical hole such as a bore hole, that passes entirely through the wall of the turbocharger casing 24 in the direction toward the blades 23 of the compressor wheel 25.

The sensor device 15 is inserted into the cylindrical passageway 26, which is tapered to accommodate the diameter of the shaft-like sensor segment 19 until its mounting segment 17 abuts on the wall of the turbocharger casing 24 from the outside. The sensor device 15 is fixed to the casing 24 by a M4 threaded bolt which is inserted through a hole in the mounting segment 17 and screwed into a corresponding bore mounting in the casing 24. The connector segment 21 extends away from the turbocharger casing 24. The distal end of the sensor segment 19 with the sensor module 12 is located at the inside opening of the cylindrical passageway 26 such that the rotating blades 23 pass by it at a short distance.

The outer diameter of the sensor segment 19 corresponds to the inner diameter of the cylindrical passageway 26 such that the sensor segment 19 tightly fits into the cylindrical passageway 26. For secure placement within the cylindrical passageway 26, an annular sealing element 27 surrounds the sensor device 15 inside the cylindrical passageway 26 to provide a secure and tight fit of the sensor device 15 within the cylindrical passageway 26. The annular sealing element 27 is disposed at the transition from the sensor segment 19 to the mounting segment 17. The annular sealing element 27 is a heat-resistant fluoro-elastomer O-ring seal that can withstand temperatures of at least 200° C.

In various embodiments, the turbocharger 22 may be for a vehicle such as an off-road vehicle, passenger car, heavy-duty truck, airplane turbine, current generating turbine, or drilling machine. As turbochargers in passenger vehicles are typically placed in the exhaust close to the engine, they have to withstand high temperatures. The sensor device 15 of the turbocharger 22 has ceramic layers as heat-resistive protective layers for the coil 11. Furthermore, the sensor device 15 is accurate and has a sensitivity particularly suitable for applications with thin turbocharger blades 23 and blades made of low conductive materials. Such applications are typically passenger vehicles using small turbochargers rotating at very high speeds, e.g. 300.000 rpm. In such a case thin blades 23 are very advantageous as they have a lower inertia moment, thus making the turbocharger 22 more responsive. Titanium blades account for increased durability of the blades 23, which is a desired property in view of the fast rotational speeds the blades have to withstand.

What is claimed is:

1. A method for manufacturing a sensor module having a passive electrical component, comprising:
punching a plurality of holes in a first green sheet of a plurality of green sheets;
forming a plurality of channels and a plurality of passageways in a second green sheet of the plurality of green sheets by using a laser on the second green sheet;
printing a metallization paste in the plurality of holes, the plurality of channels, and the plurality of passageways;
drying the first green sheet and the second green sheet with the metallization paste to form a plurality of contacts in the holes of the first green sheet, a plurality of filled channels in the channels of the second green sheet, and a plurality of filled passageways in the channels of the second green sheet, the contacts, the filled channels, and the filled passageways are part of the passive electrical component;
aligning, stacking, laminating, and sintering the plurality of green sheets together to create a sintered tile; and
separating a plurality of coils of the sintered tile in order to obtain the sensor module.

2. The method of claim 1, further comprising, before the punching step, tempering the plurality of green sheets by removing at least a part of a solvent from each of the plurality of green sheets.

3. The method of claim 1, further comprising removing a residual metallization paste between the filled channels with a laser after the drying step and before the aligning step.

4. The method of claim 3, wherein the forming step and/or the removing step are performed using a diode-pumped solid state laser.

5. The method of claim 1, wherein the forming step is carried out in at least three sub-steps until the channels are entirely formed, in each sub-step a portion of the second green sheet is removed by the laser.

6. The method of claim 1, wherein the printing step is carried out with a stencil having a polymer structure layer regulating an amount of the metallization paste printed into the channels and the passageways of the second green sheet, the stencil has a plurality of openings corresponding to the channels and the passageways.

7. The method of claim 1, wherein the sintering of the aligning step is carried out under a pressure of 0.1 MPa to 0.8 MPa.

8. The method of claim 1, wherein the aligning step is carried out after the printing step.

9. The method of claim 1, wherein the plurality of green sheets includes a third green sheet which is disposed as an outermost protective layer on the first green sheet and the second green sheet, the third green sheet having neither a plurality or channels nor a plurality of passageways.

10. A coil, comprising:
a contact formed in a passageway of a first green sheet;
a metallized passageway and/or a metallized channel of a second green sheet; and
a plurality of pads, the contact electrically connecting the plurality of pads with the metallized passageway and/or the metallized channel.

11. The coil of claim 10, wherein the metallized channel has an aspect ratio greater than one, a depth of the metallized channel is between 80 und 120 μm, a width of the metallized channel is 70 μm, and the second green sheet has a thickness of 165 μm.

12. The coil of claim 11, further comprising a plurality of metallized channels in the second green sheet, adjacent metallized channels in the second green sheet are separated by a distance between 20 und 30 μm.

13. The coil of claim 10, wherein the coil is a double-D coil or a double-D saddle coil.

14. A sensor module, comprising:
a coil including a contact formed in a passageway of a first green sheet, a metallized passageway and/or a metallized channel of a second green sheet, and a plurality of pads, the contact electrically connecting the plurality of pads with the metallized passageway and/or the metallized channel; and
a plurality of additional green sheets including an outermost green sheet that does not include metallized channels or metallized passageways, the first green sheet and the second green sheet are disposed between the outermost green sheet and one of the plurality of additional green sheets.

15. The sensor module of claim 14, wherein the pads connect the coil to an electrical circuit.

16. The sensor module of claim 15, wherein the pads are disposed on a side of the sensor module on the one of the plurality of additional green sheets.

17. The sensor module of claim 14, wherein the sensor module has a minimum diameter of 3 mm.

18. A sensor device for determining a speed of an electrically conductive object, comprising:
a sensor housing;
an electrical circuit for signal processing and data transmission disposed in the sensor housing; and
a sensor module disposed at a sensor tip of the sensor housing and facing in a direction of the electrically conductive object, the sensor module is connected to the electrical circuit and includes:
a coil including a contact formed in a passageway of a first green sheet, a metallized passageway and/or a metallized channel of a second green sheet, and a plurality of pads, the contact electrically connecting the plurality of pads with the metallized passageway and/or the metallized channel; and
a plurality of additional green sheets including an outermost green sheet that does not include metallized channels or metallized passageways, the first green sheet and the second green sheet are disposed between the outermost green sheet and one of the plurality of additional green sheets.

19. A turbocharger, comprising:
a casing;
a compressor wheel having a plurality of compressor wheel blades made of an electrically conductive material; and
a sensor device including:
a sensor housing;
an electrical circuit for signal processing and data transmission disposed in the sensor housing; and
a sensor module disposed at a sensor tip of the sensor housing and facing in a direction of the compressor wheel blades, the sensor module is connected to the electrical circuit and includes:
a coil including a contact formed in a passageway of a first green sheet, a metallized passageway and/or a metallized channel of a second green sheet, and a plurality of pads, the contact electrically connecting the plurality of pads with the metallized passageway and/or the metallized channel; and
a plurality of additional green sheets including an outermost green sheet that does not include metallized channels or metallized passageways, the first green sheet and the second green sheet are disposed between the outermost green sheet and one of the plurality of additional green sheets.

20. The turbocharger of claim 19, wherein the compressor wheel blades each have a thickness equal to or greater than 0.2 mm.

21. The turbocharger of claim 19, wherein the turbocharger is used in a vehicle, a generating turbine, or a drilling machine.
